(19) United States
(12) Patent Application Publication
(10) Pub. No.: US 2022/0373452 A1
(43) Pub. Date: Nov. 24, 2022

(54) DIFFRACTIVE IMAGING MAGNETO-OPTICAL SYSTEM

(71) Applicant: Edwin Fohtung, Niskayuna, NY (US)

(72) Inventor: Edwin Fohtung, Niskayuna, NY (US)

(73) Assignee: Rensselaer Polytechnic Institute, Troy, NY (US)

(21) Appl. No.: 17/765,054

(22) PCT Filed: Sep. 30, 2020
(86) PCT No.: PCT/US20/53428

§ 371 Date: Mar. 30, 2022

Related U.S. Application Data
(60) Provisional application No. 62/908,115, filed on Sep. 30, 2019.

(51) Int. Cl. G01N 21/17; G01N 21/21

(52) U.S. Cl. CPC G01N 21/1717; G01N 21/21; G01N 2201/0633; G01N 2201/0636; G01N 2021/1727

(57) ABSTRACT

A system for imaging, including a source of coherent light; a polarization state generator for generating polarized optical photons from the light originating in the source of coherent light; a sample environment; a polarization state analyzer for permitting photons having a desired polarization to interact with a detector; and an imaging unit for generating an image based on the interactions of the photons with the detector. The sample environment includes a plurality of electromagnets, each connected to one or more power supply components; and a controller, connected to the electromagnets and including software for generating and controlling a desired magnetic field created by each of the electromagnets in concert with each other.

### CROSS REFERENCE TO RELATED APPLICATION(S)

This application claims the benefit of U.S. Provisional Patent Application No. 62/908,115, filed Sep. 30, 2019, which is incorporated by reference as if disclosed herein in its entirety.

### FIELD

The present technology relates to methods and systems for diffractive imaging using magneto-optical techniques and to induce and control the configuration of magnetization in materials. Particularly, one embodiment of the present technology relates to a Coherent Diffractive Imaging magneto-optical microscope (“CDIMOM”) that includes an apparatus for producing programmable, adjustable, and variable complex magnetic field (“PAVCM”) at the sample; optical detectors; focusing and collimating optics; a polarizer; and an analyzer. More particularly, in one embodiment, the PAVCM comprises a multi-pole arrangement of programmable magnets for inducing complex configurations of magnetic polarization. Optical, sample, and detecting equipment complete the desired microscopic setup in this embodiment.

### BACKGROUND

Instrument scientists at synchrotron and neutron sources can use programmable magnetic sample setup on magnetic diffraction and imaging beamlines to study complex magnetic topologies. Academia, including professors and researchers of sciences such as physics, material science, engineering, chemistry and medicine, frequently has limited funds for optical research, especially at underprivileged universities. At the same time, younger professors apply for grants to buy equipment for their laboratories, but the funds available for optical setups are limited.

Optical research equipment is often very expensive. Faraday and Kerr microscopes currently cost from $350,000 to $500,000. There is also often a long delay between the time a researcher receives a grant and when he or she receives such a microscope, due to the need for the researcher to specify the desired characteristics of the machine.

Further, Faraday and Kerr microscopes are often bulky due to the need to keep the sample environment cool and have limited resolution (about half the wavelength) given by the numerical aperture of the imaging system.

Currently, there are a number of solutions for creation and modulation of complex configurations of magnetization in materials for memory storage and information. Some of these solutions attempt to use permanent magnets mounted on mechanical positioning systems to achieve the task, but these solutions cannot provide adjustable direction, shape, amplitude and frequency of the applied magnetic field. Other solutions attempt to use multi-axis Helmholtz coils, but these solutions cannot be used as highly localized sources of the magnetic field and when the control of direction is needed with finer precision, since available systems are complex and bulky. Moreover, these solutions require high current power supplies to achieve sufficient levels of magnetic field, making the supporting infrastructure more complex, expensive, and requiring special safety training for operation.

Further, a microscopic setup usually uses helium and nitrogen to keep the sample environment cool. Ice formation during measurement at low temperatures is another issue of regular optical measurement.

Therefore, what is needed is a versatile measuring optical setup at a reasonable price. There is also high demand for high resolution of images, and versatility of the optical setups. What is also needed are setups that can achieve the acceptable results without the cryogenic camera, which would reduce the bulkiness of the setup and completely eliminate the need for nitrogen and helium.

### SUMMARY

One embodiment of the present technology relates to a CDIMOM that includes a programmable adjustable magnetic setup, embodiments of which reduce several hurdles that impede optical measurements and also provides enhancements in the resolution of the images. This technology is applicable in multiple industries, including data storage and medical measurements.

Some embodiments of the present technology are useful for academic and industrial research laboratories that study complex magnetic materials for potential applications in elements of electronics, study magnetic materials and magnetic effects for application in medicine and biology, and perform fundamental research. Some embodiments are useful for the space industry, where parts are exposed to varying magnetic fields, both during the design and testing cycles and during the quality control process.

One embodiment of the present technology relates to a CDIMOM including an apparatus for producing programmable adjustable and variable complex magnetic fields known as a Programmable Multi-Pole Magnetic System (“PMPMS”) for inducing complex configurations of magnetic polarization. In some embodiments, the PMPMS system includes a multi-pole arrangement of programmable magnets for inducing complex configurations of magnetic polarization along with the required optical, sample, and detecting environment to complete the desired microscopic setup. In some embodiments, CDIMOM is diffraction limited and achieves a resolution that is better than half the wavelength.

The architecture of a magnetic sample holder according to one embodiment allows the system to supply a multi-pole complex magnetic field configuration with variable shape, amplitude, and frequency to the material.

Another embodiment of the present technology relates to an optical system, for use with X-ray frequencies and neutron sources. The system according to some embodiments of the present technology can be integrated into synchrotron, microscopy, neutron, and magneto-electric instruments such as those used for device testing and for monitoring modifications of samples in real time.

According to one embodiment of the present technology a system for imaging is provided. The system includes a source of coherent light, a polarization state generator for generating polarized optical photons from the light originating in the source of coherent light, a sample environment, a polarization state analyzer for permitting photons having a desired polarization to interact with a detector, and an imaging unit for generating an image based on the interactions of the photons with the detector. The sample environment includes a plurality of electromagnets, each connected to one or more power supply components, and a controller connected to the electromagnets and including software for generating and controlling a desired magnetic field created by each of the electromagnets in concert with each other.

In some embodiments, one or more electronic circuits bridge the one or more power supply components to the electromagnets. In some embodiments, the electronic circuits supply voltage to the electromagnets to generate the desired magnetic field. In some embodiments, the sample environment creates a multi-pole complex magnetic field with variable shape, amplitude, and frequency. In other embodiments, the sample environment creates a rotated magnetic field. In some embodiments, the rotated magnetic field has a magnetic flux density of 0.5 T and a frequency of up to 60 KHz.

In some embodiments, the sample environment further includes a sample holder positioned such that the plurality of electromagnets surround the sample holder.

In some embodiments, each of the plurality of electromagnets are held within a magnet holder and located in a magnet housing positioned to surround a sample holder in the sample environment. In some embodiments, the magnet housing is rotatable around the sample holder. In some embodiments, the magnet housing has an octagonal shape. In other embodiments, the magnet housing has an annular shape.

In some embodiments, the system further includes one or more filtering optics positioned between the polarization state generator and the sample environment. In some embodiments, the system further includes one or more collimating optics positioned between the polarization state generator and the sample environment. In some embodiments, the system further includes one or more alignment mirrors positioned between the polarization state generator and the sample environment.

In some embodiments, the sample environment is a cryo-free environment.

In some embodiments, the polarization state analyzer is reconfigurable between a plurality of modes. In some embodiments, one of the plurality of modes is an imaging mode. In some embodiments, one of the plurality of modes is a diffraction mode.

According to another embodiment of the present technology, a method of creating Neel type skyrmion domains in a sample is provided. The method includes placing the sample in a sample environment, the sample environment including a sample holder and a plurality of electromagnets arranged to surround the sample holder, and applying a rotated magnetic field generated by the plurality of electromagnets to the sample to induce bubble skyrmionic polarization dipole textures in the sample.

In some embodiments, the sample environment further includes one or more power supply components connected to each of the plurality of electromagnets; one or more electronic circuits to bridge the one or more power supply components to the electromagnets, wherein the electronic circuits supply voltage pulses to the electromagnets to generate the rotated magnetic field; and a controller connected to the electromagnets and including software for controlling the magnetic field. In some embodiments, the rotated magnetic field has a magnetic flux density of 0.5 T and a frequency of up to 60 KHz. In some embodiments, the sample environment is a cryo-free environment.

In some embodiments, the sample includes a uniaxial centrosymmetric ferromagnetic thin-film material. In some embodiments, the sample includes Y₃Fe₅O₁₂.

Further objects, aspects, features, and embodiments of the present technology will be apparent from the drawing figures and below description.

### BRIEF DESCRIPTION OF DRAWINGS:

FIG. 1A shows a perspective view of a CDIMOM according to an embodiment of the present technology. FIG. 1B shows a schematic view of the polarization state analyzer block of the CDIMOM of FIG. 1A in an imaging mode. FIG. 1C shows a schematic view of the polarization state analyzer block of the CDIMOM of FIG. 1A in a diffraction mode. FIG. 1D shows a schematic view of the sample environment block of the CDIMOM of FIG. 1A. FIG. 1E shows an exploded view of the magnetic system of the sample environment block of FIG. 1D. FIGS. 1F and 1G show exemplary images obtained by the CDIMOM of FIG. 1A for magnetic microscopy and diffraction microscopy, respectively.

FIG. 2A shows a schematic view of a first polarizer and analyzer orientation used in a Polarimetric Coherent Diffractive Imaging system according to an embodiment of the present technology. FIG. 2B shows images taken with the system of FIG. 2A. FIG. 2C shows a schematic view of a second polarizer and analyzer orientation used in the Polarimetric Coherent Diffractive Imaging system. FIG. 2D shows images taken with the system of FIG. 2C. FIG. 2E shows a sample for imaging using the Polarimetric Coherent Diffractive Imaging system of FIGS. 2A and 2C. FIG. 2F shows a Mueller's matrix obtainable with the images taken by the system.

FIG. 3A shows a schematic view of a Y₃Fe₅O₁₂ (“YIG”) sample in a CDIMOM used for the creation of Neel type skyrmion in uniaxial centrosymmetric ferrimagnetic thin-film at room temperature according to an embodiment of the present technology. FIG. 3B shows a perspective view of the sample on a substrate.

FIGS. 4A-9B show images of in-plane magnetic fields generated by various positioning of the programmable magnets of the CDIMOM of FIG. 3A, and the corresponding polarized coherent diffraction patterns for the respective magnet positions.

FIGS. 10A-10B show simulated and measured polarized coherent diffraction patterns for a rotated magnetic field according to an embodiment of the present technology.

FIG. 11A shows simulation results of stripe domains of the YIG sample without applying a rotated magnetic field. FIG. 11B shows the magnetic distribution on the top surface of the YIG sample.

FIG. 12A shows simulation results of skyrmion-like domains of the YIG sample after applying the rotated magnetic field. FIG. 12B shows the magnetic distribution on the top surface of the YIG sample.

FIG. 13 shows experiment results of the stripe domains of the YIG sample without an external magnetic field.

FIGS. 14A-14D show experiment results of the skyrmion domain structure formed in the YIG sample under an external field Hz along the z-axis of the YIG sample.

FIGS. 15A-D show experimental results of the skyrmion domain structure formed in the YIG sample under a cycled external field.

FIG. 16A shows gradient magnitude and gradient direction images of the stripe domains of the YIG sample without applying the rotated magnetic field. FIG. 16B shows the gradient images of the skyrmion-like domains of the YIG sample after applying the rotated magnetic field.

FIGS. 17A-17C show images of top, central, and bottom slices, respectively, of the YIG sample showing a skyrmion-to-bubble-to-skyrmion transformation.

### DETAILED DESCRIPTION

Accordingly, embodiments of the present technology are directed to a programmable multi-pole magnet device that can be applied in magneto-electronic devices, magnetic microscopy and magnetic imaging microscopes, diffraction microscopy, super-resolution birefringent diffractive imaging (“Sr-BDP”) (which generates contrast via computer processing of polarized light scattered differently by tissues with different birefringences, and enables tissue and cell imaging in-vivo without staining or abusive contrast agents), synchrotron imaging and spectroscopy, biomedical research on drug delivery, space research and engineering, and device testing and reconfiguration. Some embodiments achieve the same results at room temperature that Faraday and Kerr microscopes achieve, but without the need for the bulky cooling chambers of Faraday and Kerr microscopes.

In some embodiments, the programmable multi-pole magnet device includes an arrangement of electro-magnets on electro-magnet holders that are used to induce magnetism and to control the configuration of magnetization in materials such as thin films, heterostructures and bulk crystals. In some embodiments, the components that comprise the magnet device are: electro-magnet holders, an arrangement of electromagnets attached to electro-magnet holders, power supply, electronic circuit, a microcontroller, and a control system for the device control. Generally speaking, these components are structured, in some embodiments, such that the microcontroller controls the electronic circuit that allows the delivery of voltage pulses with variable shape, amplitude, and frequency from the power source to the individual electro-magnets. In some embodiments, the microcontroller controls the electronic circuit that permits control of the supply voltage in a programmable way, while the electronic circuit bridges the power supply with individual electro-magnets, thus supplying them with voltage to generate a reproducible complex configuration of the magnetization on the material. Preferably, this architecture allows the system to supply a multi-pole complex magnetic field configuration with variable shape, amplitude, and frequency to the sample material.

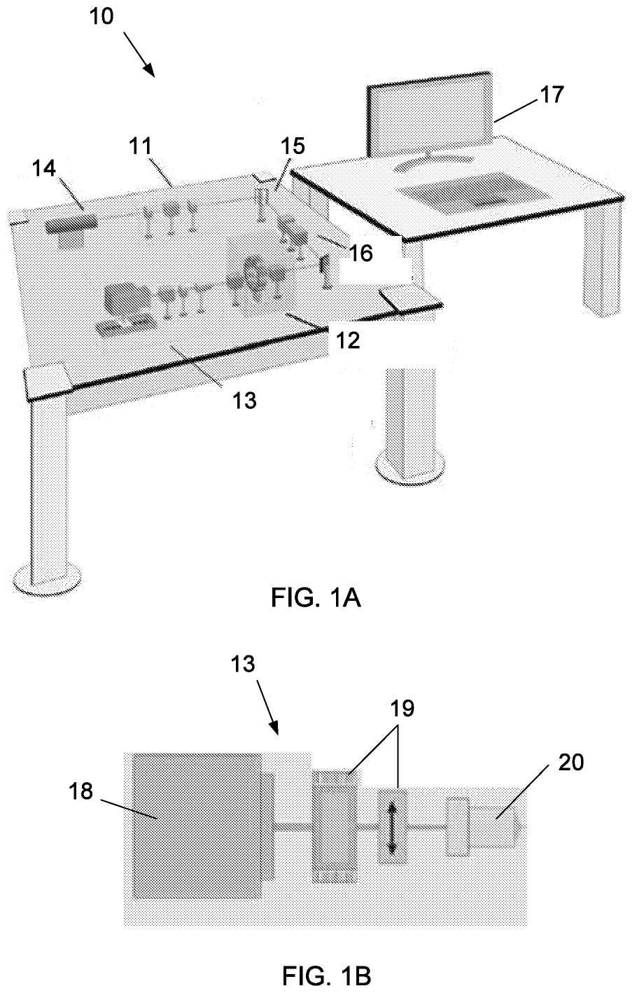

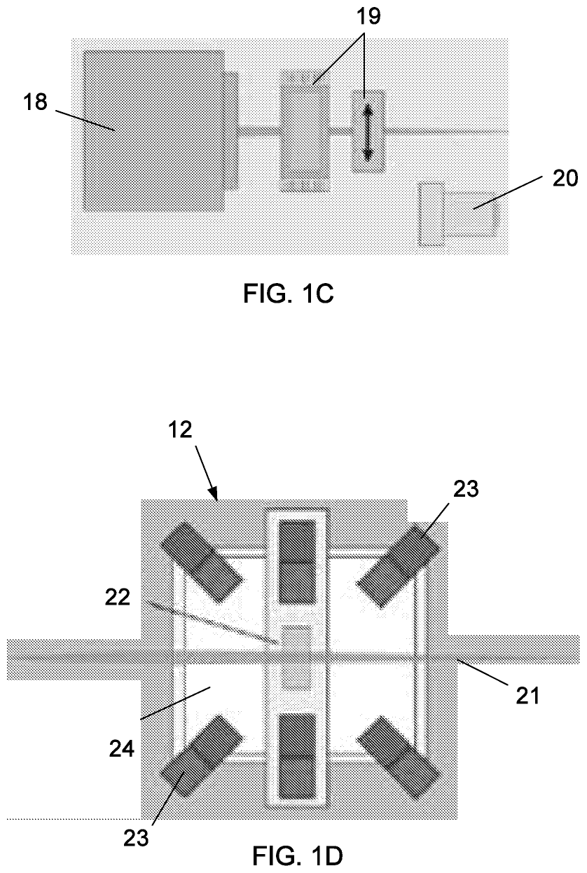

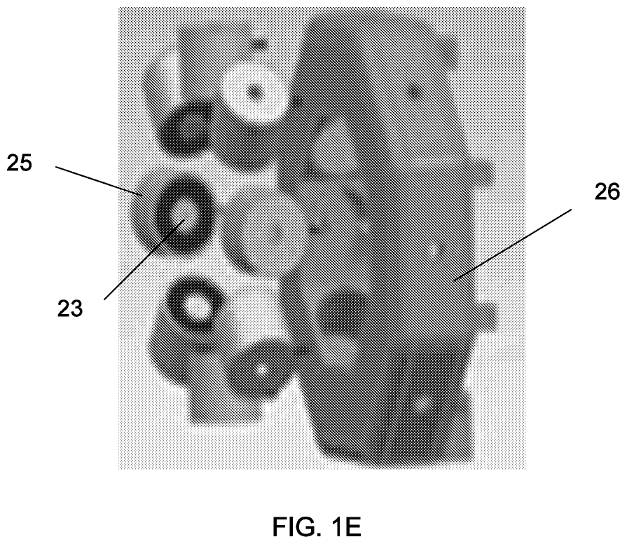

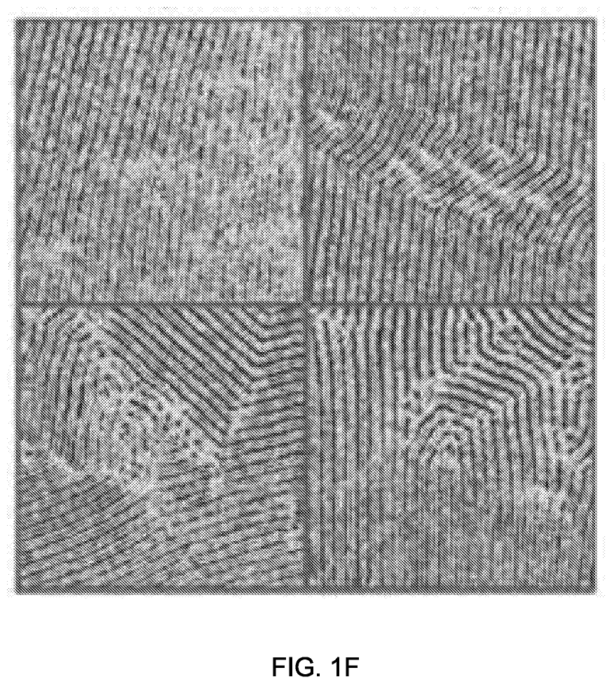

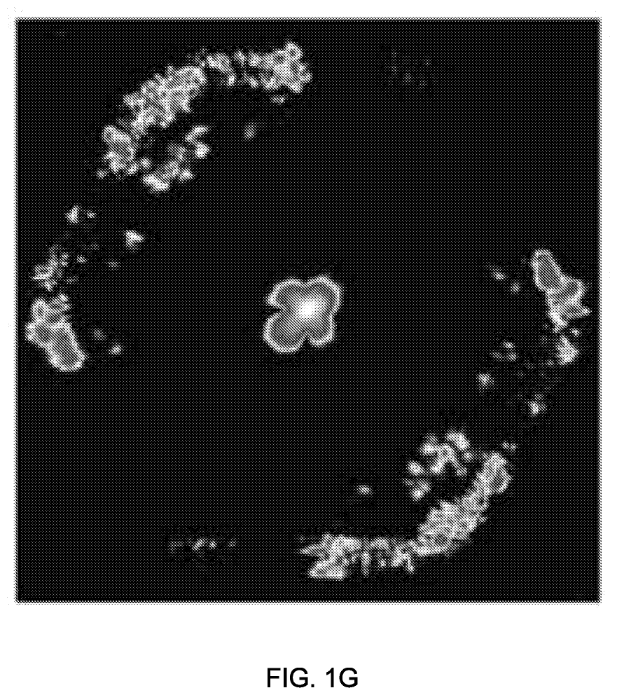

In some embodiments, the programmable multi-pole magnet device is a CDIMOM 10 that is capable of both generating complex topologies of magnetic textured polarization and also imaging these textures, as shown in FIG. 1A. In some embodiments, the CDIMOM 10 includes three major blocks: a polarization state generator 11, a sample environment 12, and a reconfigurable polarization state analyzer 13. CDIMOM 10 also includes a laser source 14. In some embodiments, CDIMOM 10 includes one or more alignment mirrors 15 for redirecting a laser beam emitted from the laser source 14. In some embodiments, CDIMOM 10 includes a beam filtering block 16. In some embodiments, beam filtering block 16 includes one or more filtering and/or collimating optics. In some embodiments, CDIMOM 10 is part of a programmable multi-pole magnet system that includes a control station 17 for controlling the CDIMOM 10 and analyzing data from the CDIMOM 10. Preferably, control station 17 includes software for controlling the magnetic field generated by the programmable multi-pole magnet device. Such software preferably includes instructions for the microcontroller to control the electronic circuit that supplies voltages from the power supply to the magnets to generate a desired magnetic field. In some embodiments, the control station 17 is connected, via the microcontroller and electronic circuits through wired or wireless connections, to the plurality of magnets.

Preferably, the polarization state generator block 11 creates tunable polarized (elliptical, horizontal, circular left/right, 45-degrees, etc.) optical photons. In some embodiments, the polarization state analyzer block 13 includes a detector 18, one or more polarization optics 19, and a microscope 20, as shown in FIG. 1B. In some embodiments, the polarization state analyzer block 13 includes an imaging unit. In some embodiments, the imaging unit forms data received from the detector 18 into an image for analysis by the control station 17. In some embodiments, the imaging unit is in communication (via a wired or wireless connection) with the control station 17. In some embodiments, the polarization state analyzer block 13 is reconfigurable for use in different modes, such as an imaging mode using the microscope 20, as shown in FIG. 1B, and a diffraction mode that does not use the microscope 20, as shown in FIG. 1C. The reconfigurable polarization state analyzer 13 has the capability of allowing photons of laser beam 21 of specific polarization scattered by a magnetic sample 22 to hit the detector plane 18. In some embodiments, the sample environment block 12 includes an apparatus for producing programmable, adjustable, and variable complex magnetic fields. As shown in FIG. 1D, the sample environment block 12 includes a sample 22 within a magnetic system having a multi-pole arrangement of a plurality of programmable magnets 23 for inducing complex configurations of magnetic polarization of the photons of laser beam 21. In some embodiments, each of the plurality of programmable magnets 23 is placed within a magnet holder 25, which are all held within a housing 26, as shown in FIG. 1E. Preferably, housing 26 is shaped such that the magnets 23 surround the sample 22, such as an annular shape, octagonal shape, etc. In some embodiments, the magnetic setup is capable of applying 0.5 T magnetic field in a circular and sequential manner at a frequency of up to 60 KHz rate. In some embodiments, the sample 22 is placed in a cryo-free environment 24, which permits the power of the vectoral magnetic systems to induce bubble and skyrmionic domains at room temperature. FIGS. 1F and 1G show exemplary images taken by the CDIMOM 10 used for magnetic microscopy and diffraction microscopy, respectively.

Some embodiments of the present technology comprise a compact CDIMOM 10 for sub-optical wavelength characterization (imaging and diffraction) of magnetic polarization. Some embodiments of the present technology include a programmable multi-pole magnetic setup that is capable of inducing bubble skyrmionic magnetic polarization dipole texture at room temperature in magnetic materials. Some embodiments include a method for inducing and imaging highly mobile topological magnetic spin textures in epitaxial magnetic films, for example, Y₃Fe₅O₁₂ (“YIG”) thin films, permalloy, FePt, CoPd, and other films.

The embodiment shown in FIG. 1A is directed to a magnetic flux-based approach to manipulating and detecting using polarized coherent diffraction imaging. In this embodiment, CDIMOM 10 includes a programmable multi-pole magnetic device that enables the induction of a complex configuration of magnetization on a target material 22, the device preferably comprising an arrangement of electromagnets 23 on electromagnets holders 25 that can be used to induce magnetism and to control the configuration of magnetization in materials 22 such as thin films, for example YIG films on a substrate, heterostructures, and bulk crystals. The system preferably comprises electromagnet holders 25, an arrangement of electromagnets 23 attached to the electromagnet holders 25, a power supply, an electronic circuit, a microcontroller, and a control system 17. The programmable microcontroller preferably controls the electronic circuit that delivers voltage pulses with variable shape, amplitude, and frequency from the power source to the individual electromagnets 23. The electronic circuit bridges the power supply with individual electromagnets 23, thus supplying them with voltage to generate a reproducible complex configuration of the magnetization on the target material 22. The system can thus provide a multi-pole complex magnetic field configuration with variable shape, amplitude, and frequency to the material 22. Preferably, the system can also apply magnetic field from different directions; control the shape of applied magnetic field pulses and their duration; apply a magnetic field locally on the sample 22; and reduce complexity of the system, such as its size, cost of operation, and safety requirements. Other advantages include multi-directional field control; adjustable field strength, direction, and pulse profiles; portable instrument with modular design and scalability; integration into various research systems; applicable for machine learning on new magnetic materials; requires less maintenance compared to systems with multiple Helmholtz coils; has increased versatility compared to existing systems; provides a programmable complex configuration of magnetic field; enables control of direction, shape, amplitude, and frequency of the generated magnetic field; can generate both varying and static magnetic field depending on the magnetic field sources used; and can generate both extended and localized magnetic fields.

Embodiments of the present technology are useful for academia, industry, and research laboratories that study complex magnetic materials for potential applications in elements of electronics, study magnetic materials and magnetic effects for application in medicine and biology, and perform fundamental research. The present technology is also useful for the space industry, where parts are exposed to varying magnetic fields, both during the design and testing cycles and during the quality control process. Other applications include engineering new magnetic domain textures and polarized coherent diffraction patterns to detect them in magneto-electronic devices, magnetic microscopy and magnetic imaging microscopes, diffraction microscopy, Sr-BDI, synchrotron imaging and spectroscopy, biomedical research on drug delivery, space research and engineering, and device testing and reconfiguration. The system can be integrated into synchrotron, microscopy, neutron, and magneto-electric instruments such as those used for device testing and for monitoring modifications of samples in real time.

The directional dependence of the index of refraction contains a wealth of information about anisotropic optical properties in magnetic, semiconducting, and insulating materials. Some embodiments of a CDIMOM according to the present technology provide a high-resolution lens-less technique that uses birefringence as a contrast mechanism to map the index of refraction and magnetic topological texture distribution in optically anisotropic materials.

In one embodiment, a CDIMOM based on optical birefringence was applied to a YIG film using polarized light from a helium neon laser. In other embodiments, this approach is applied to imaging with diffraction-limited resolution, including with the use of brilliant X-ray sources. Applications of this imaging technique are in electronic devices, for example, in which both charge and spin carry information as in multiferroic materials and photonic materials such as light modulators and optical storage.

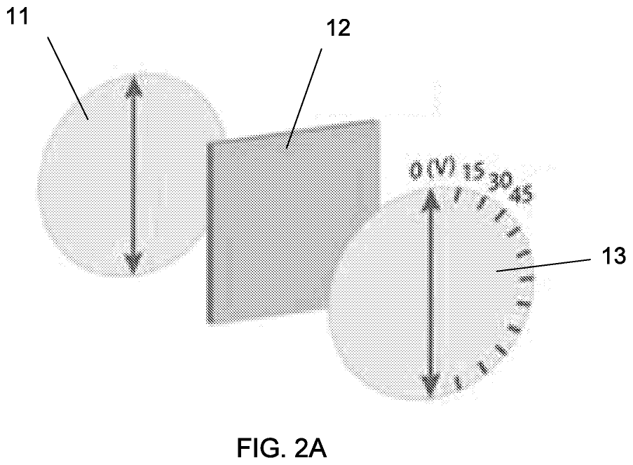

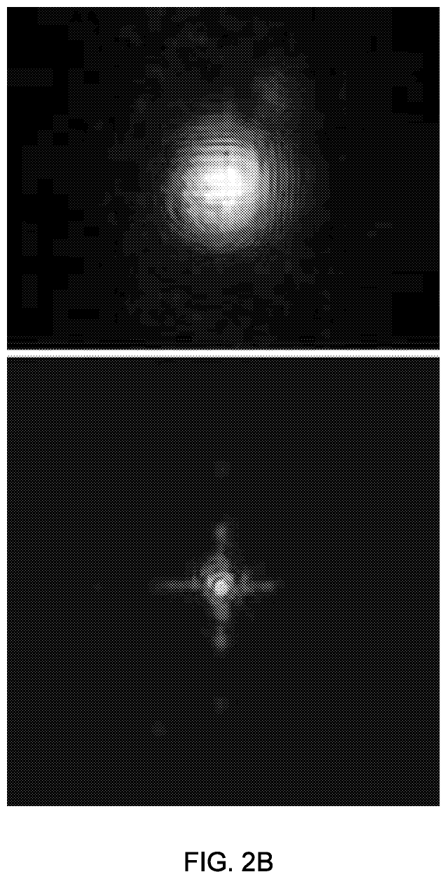

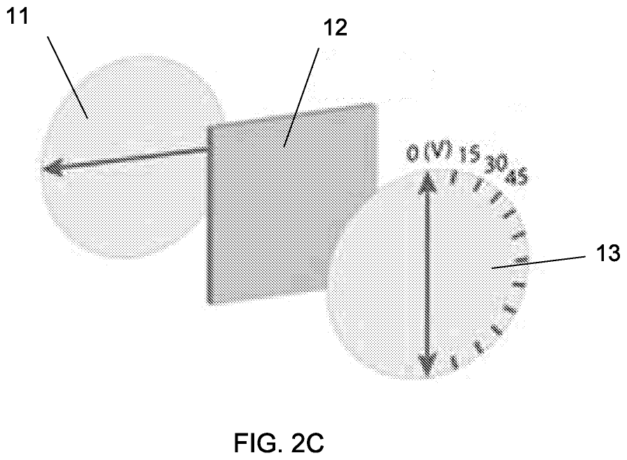

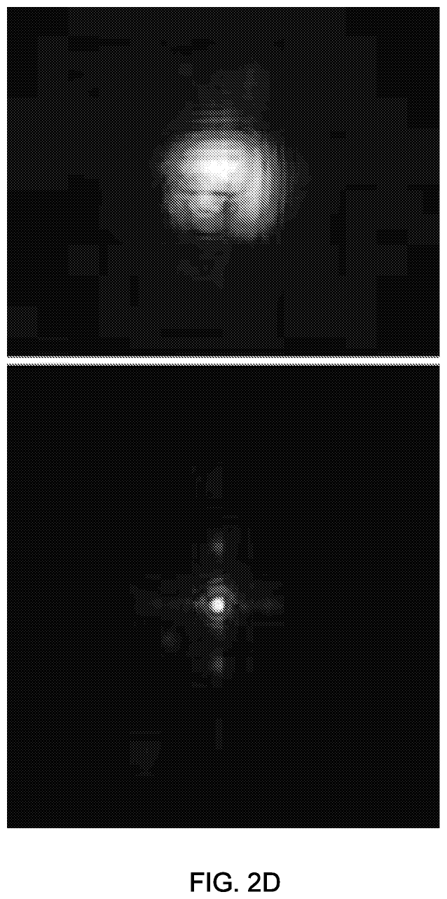

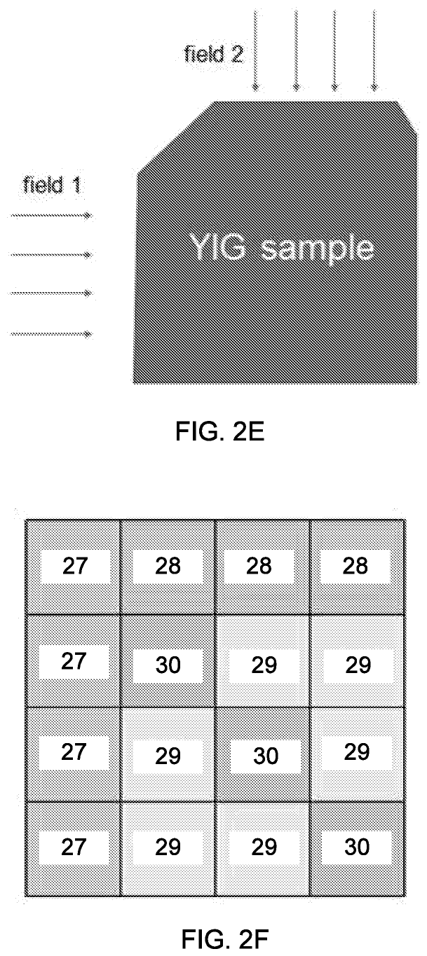

Some embodiments of the present technology are directed to a Polarimetric Coherent Diffractive Imaging system. In anisotropic (magnetic, ferroelectric, semiconducting) materials with lower than cubic symmetry, the index of refraction, dielectric and susceptibility constant generally depends on the polarization and propagation direction of the traversing light. Properties of materials related to dichroism, depolarization, and birefringent can be reconstructed using iterative phase retrieval algorithms. An exemplary embodiment of the bottle-neck of this experimental setup is the presence of an analyzer 13 and a polarizer 11 in the scattering geometry of the experiment, with the sample 22 mounted between them as shown in FIGS. 2A and 2C, which show two Polarimetric coherent diffractive measurement modes namely; measurement-1 and measurement-2. In measurement-1, both the polarizer 11 and analyzer 13 are set to vertical polarization. This implies the sample 22 is illuminated with horizontally polarized light, while the analyzer 13 only allows horizontally scattered light from the sample 22 to be measured. In measurement-2, the polarizer 11 is kept at horizontal while the analyzer 13 is rotated to vertical. FIGS. 2B and 2D show images of measurement-1 and measurement-2, respectively. In polarimetric coherent diffractive imaging, a series of scattered patterns can be measured while rotating the analyzer 13 relative to the polarizer 11. FIG. 2E shows an embodiment of such measurement from a magnetic YIG sample, with two possible field directions shown as field 1 and field 2. FIG. 2F shows that diffraction images making up the typical Mueller's matrix can be obtained. Each diffraction matrix element contains unique encode information about the material. In some embodiments, matrix element 27 refers to measurements with un-polarized laser inputs, matrix element 28 refers to dichroism components, matrix element 29 refers to birefringence components, and matrix element 30 refers to depolarization components. This diffraction can be reconstructed using iterative phase retrieval algorithms to obtain real images of the sample property such as magnetic susceptibility and index of refraction.

Some embodiments of the present technology are directed to a Birefringent Coherent Diffractive Imaging system. In magnetic materials with lower than cubic symmetry, the index of refraction generally depends on the polarization and propagation direction of the traversing light. This anisotropy is due to the directional dependence of material properties and the broken symmetry in the optical axes of these materials. The analysis of the propagation of light shows that uniaxial materials are characterized by two indices of refraction, one parallel to the optical axis nₑ, and two degenerate indices of refraction in the plane perpendicular to the optical axis n₀. This phenomenon is known as Birefringence. The index of refraction for intermediate propagation directions interpolates smoothly between these two limiting values and is predictable from the laws of light propagation in optically anisotropic media. However, the limiting values themselves as well as their difference (birefringence) depend on material composition, crystallography, and symmetry. Capturing microscopic (local) 3-dimensional variations of the birefringence on a nanometer scale is challenging due to the limited resolution of lens based optical microscopy. In another embodiment of the present technology, a method is provided to overcome this limitation by using birefringence as a contrast mechanism for imaging the variability of optical properties in materials with nanometer resolution. A wide variety of materials including magnetic, liquid crystals, polymers and other soft matter show birefringence due to anisotropically distributed bonds. In condensed matter systems with magnetic, ferroelectric, and even multiferroic properties, birefringence can be manifested as electro- and magneto-optical phenomena which can play key roles in photonic technology enabling light modulators, optical data storage, sensors, and numerous spectroscopic techniques.

In some embodiments, the CDIMOM 10 of FIG. 1A was used for the data acquisition of a Birefringent Coherent Diffraction Imaging system. In some embodiments, the system includes a coherent light source 14 capable of producing 633 nm HeNe polarization stable laser in conjunction with 30 μm pinhole and 50 mm plano-convex lens as coherent illumination source that is spatially filtered and propagates as a parallel beam. In some embodiments, downstream from the illuminating lens, polarizing block 11 includes a tunable polarizer that allows the modification of polarization state of the transmitted light by adjusting a phase-plate position. The tunable polarizer allows for the scan of the response of the sample to different incident polarization states of the light so that intrinsic birefringent properties of the sample 22 are studied through the polarimetric approach, as described above. Furthermore, a masking 800 μm pinhole is used right before the sample 22 to improve the reconstruction convergence by isolating the region of interest and probing it with a beam of known spatial properties. To record the image of the sample 22 in reciprocal space, a 100 mm plano-convex lens was set up one focal length away from the sample. Fourier transforming properties of a real lens were used to form the reciprocal space image on the sensor of pco.pixelfly CCD camera. The image acquisition was thus done in coherent diffraction microscopy mode with additional polarization parameter. The images were acquired at 36 polarization states of the incident wave. Each dataset contained 400 frames that were later averaged to increase the signal-to-noise ratio of the final images and for each of the diffraction datasets 400 frames without illumination were captured for dark-noise correction. Each frame was taken with 65 μs exposure time so that the effects of long exposure noise are avoided.

In some embodiments, a Fienup hybrid input output (“HIO”) algorithm was used to reconstruct the birefringent density maps and light illumination probe. The square-root values of the integrated diffraction intensities are used as constraints in reciprocal space. In some embodiments, reconstructions are performed by starting from an array of random numbers and running 400 iterations of the HIO algorithm. It was noted on average after 300 iterations of the HIO algorithm, that the algorithm was circling around a solution region, so the final 100 iterations of the HIO algorithm were collected and averaged to produce a smoother and high quality reconstruction. The real space constraint reflecting the illumination region is generated from the pinhole scattering measurement with the aid of the Marchesini shrink wrap algorithm. In some embodiments, the real space constraint reflecting the illumination region is determined from an optical microscopic image of the pinhole aperture.

When light propagates through an optical media the polarization can change as a result of a change in the amplitude (dichroism) or phase shift (birefringence) of the electric vector. It is possible to determine the anisotropic properties of media determined from these two optical features. In some embodiments, Quantitative Birefringent Density Maps Δn (r) were obtaining by scaling the reconstructed phases Δϕ (r) by the calculated scaling factor. Some embodiments assume that the optical axis has a component that is uniaxial, planar oriented, and perpendicular to the propagation direction. Two directions of differential absorption are found and the intensity of the two distinct polarization direction of the transmitted beam in the sample is expressed in terms of the absorption coefficient along the ordinary direction αₒ and extraordinary direction αₑ:

IIₒ=I₀ exp[αod], lₑ=I₀ exp[αₑd] (1)

where Iₒ and Iₑ are transmitted intensities along the ordinary and extraordinary directions, respectively, and d is the thickness of the sample. Since the arbitrarily polarization states of photons β that enter the sample suffer a retardation and if the embodiment is well aligned with the principal axis of the component, then the Jones matrix J, corresponding to that of a retarder with real refractive index n₁ and n₂, is obtainable. Some embodiments account for the complex absorption in both principle directions, by introducing the correction: n₁=nₑ+ikₑ and n₂=nₒ+ikₒ. To determine the relationship between the complex part of the index of refraction kᵢ and the absorption coefficients αᵢ, embodiments having the sample illuminated with a vertically polarized photon beam corresponding to the quantum mechanical vector state represented in Jones notation is used.

In some embodiments, to characterize the quality of the reconstructed magnetic textures in the drawing figures, the concept of the phase retrieval transfer function (“PRTF”) is used. The PRTF defined as the ratio of the reconstructed diffraction amplitude (the absolute value of the Fourier transform of the reconstruction) to the measured diffraction amplitude as a function of momentum transfer. PRTF is a success metrics used to assess the fidelity and quality of the reconstruction. From PRTF one can judge on the range of frequencies over which the reconstructed information can be trusted with given confidence. There are a number of contributions that compromise the reconstruction, such as camera noise, mechanical instability of the equipment, and light source stability over the measurements time.

In some embodiments, given a reconstructed complex image S (r) obtained by phase retrieval starting from random phases, and its Fourier transform A (Q)=|A| exp {iϕ (Q)}, the PRTF is defined as:

PRTF(Q)=|A(Q))|/|I(Q)|I (2)

where I (Q) is the measured diffraction intensity, and denotes averaging over many independent reconstructions. The diffraction phases are averaged over constant frequency contours to produce the PRTF, which takes a value of 1 where the iterative algorithm consistently produced perfect convergence and a value near 0 where the algorithm continually failed to converge.

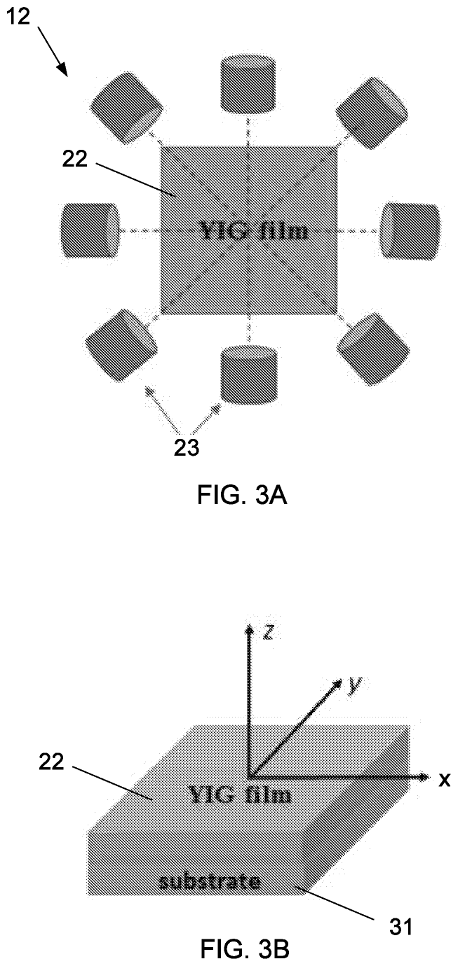

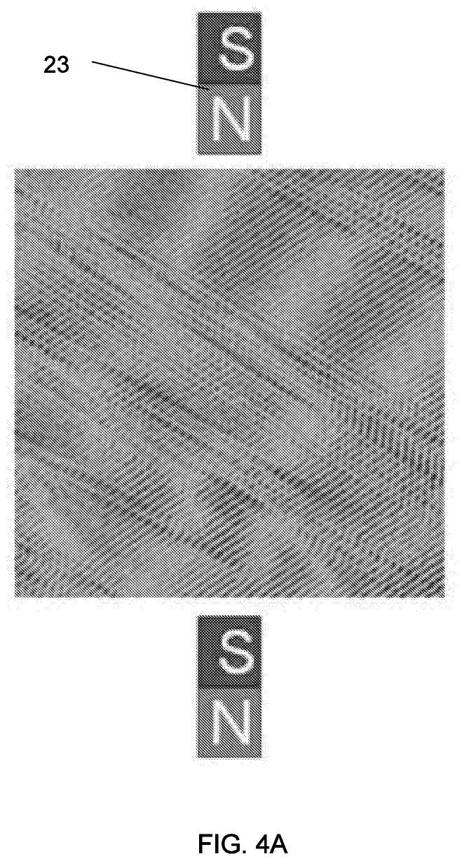

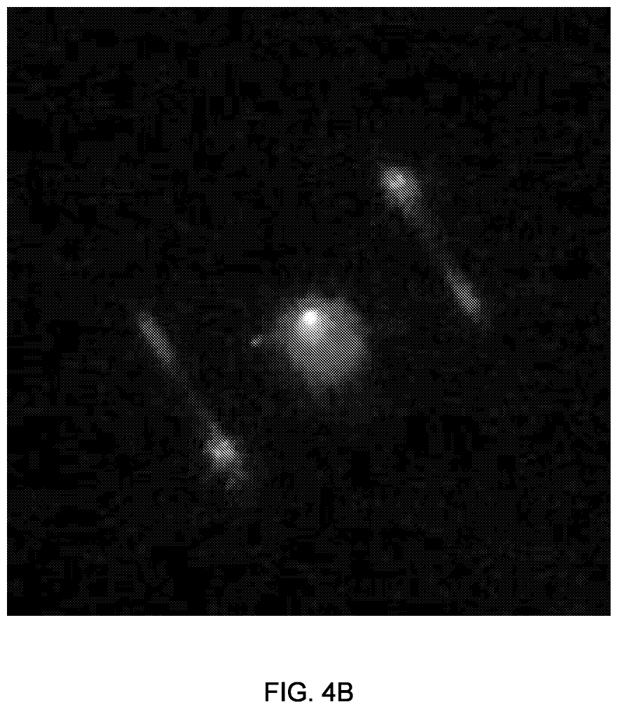

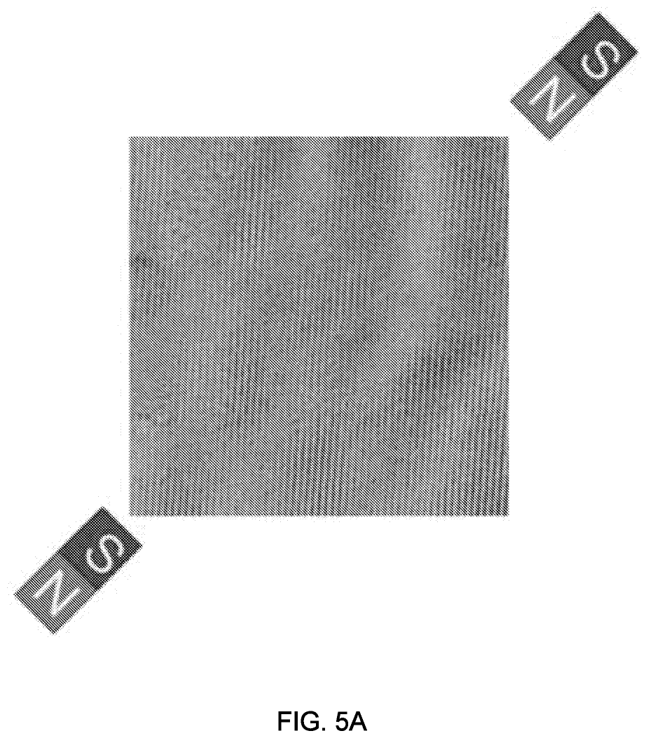

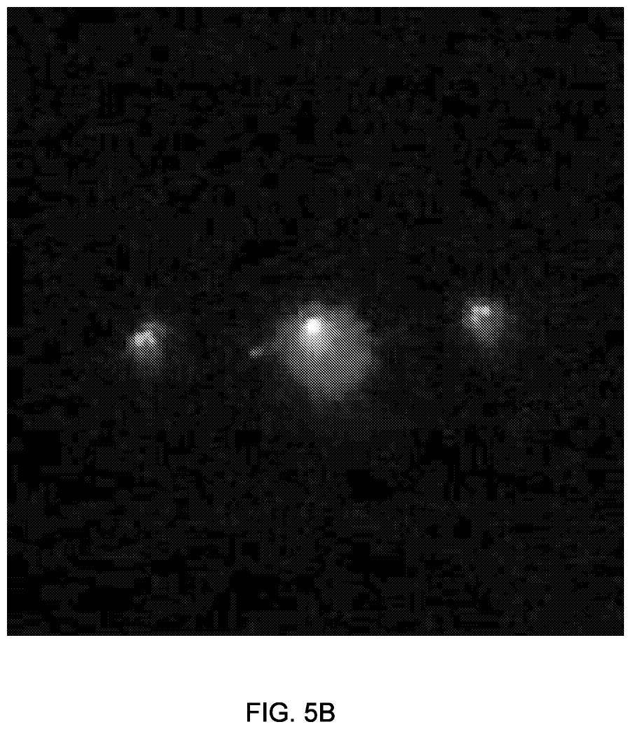

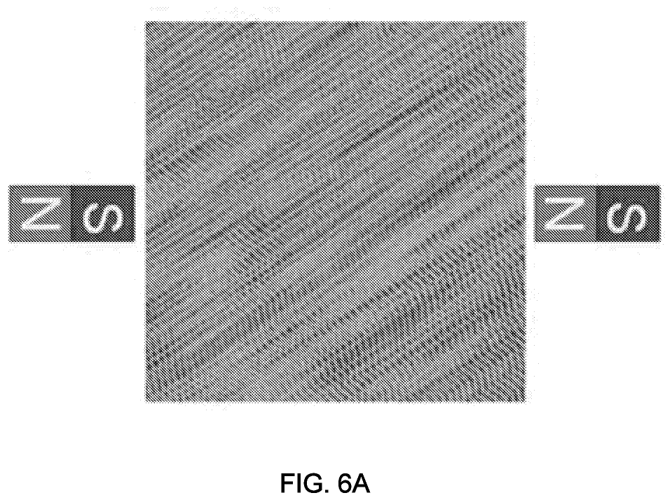

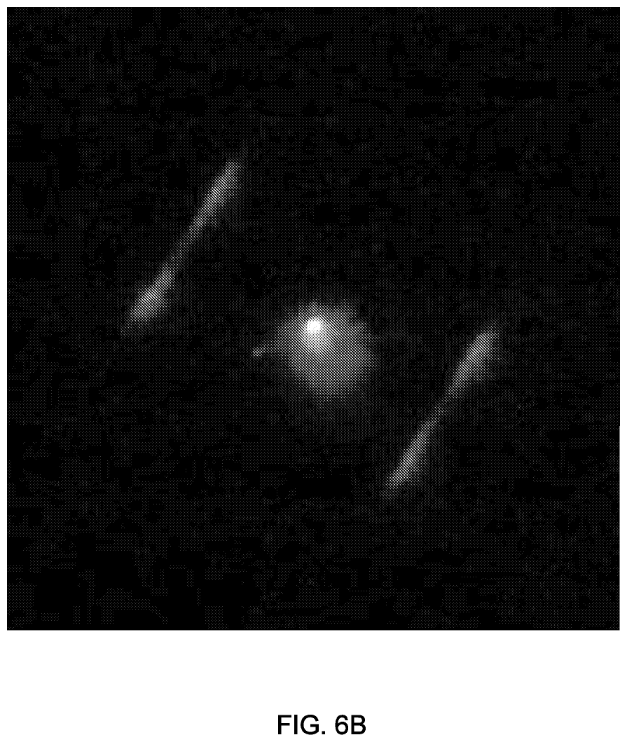

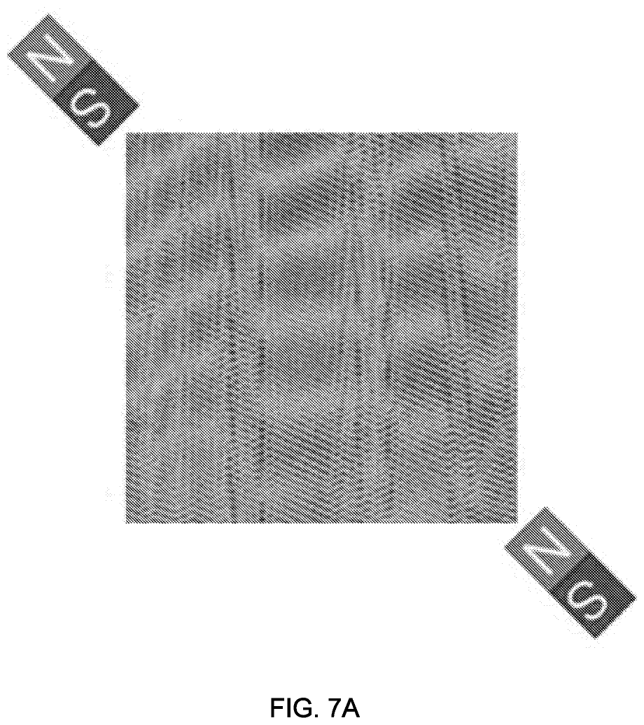

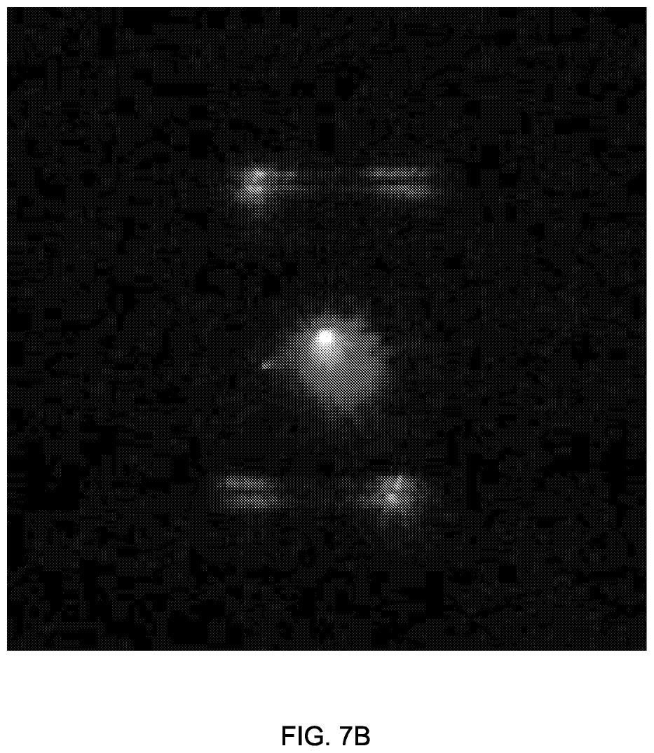

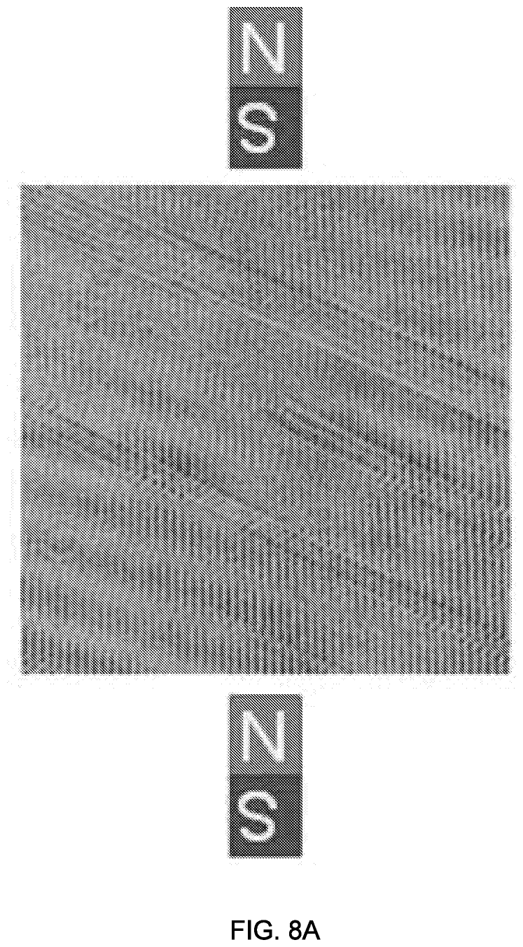

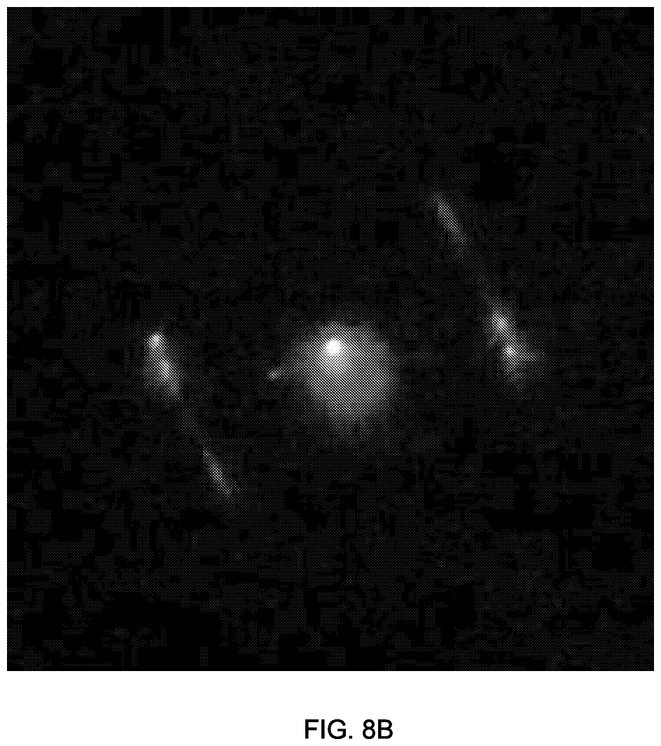

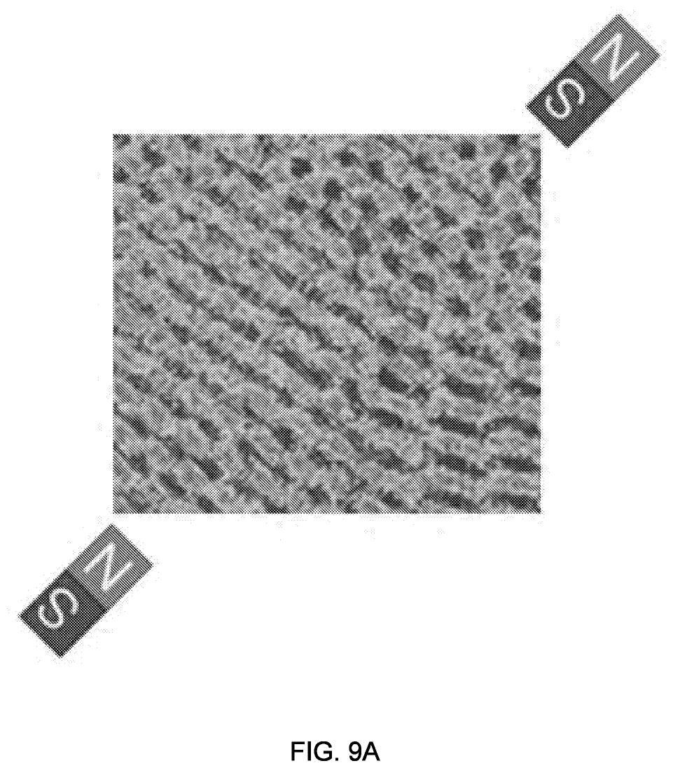

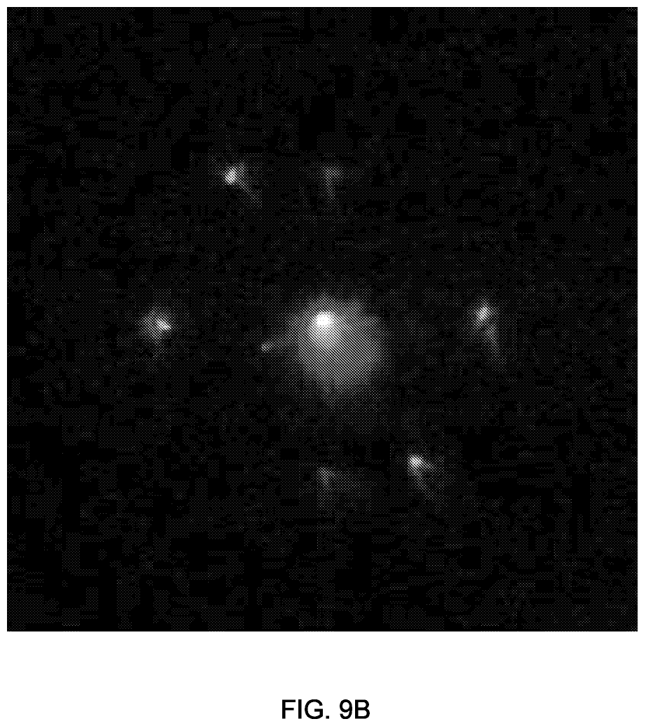

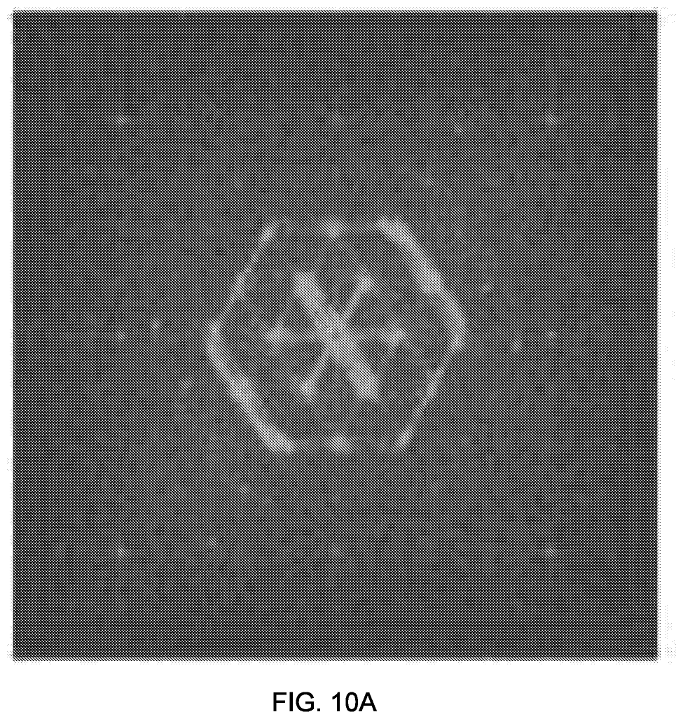

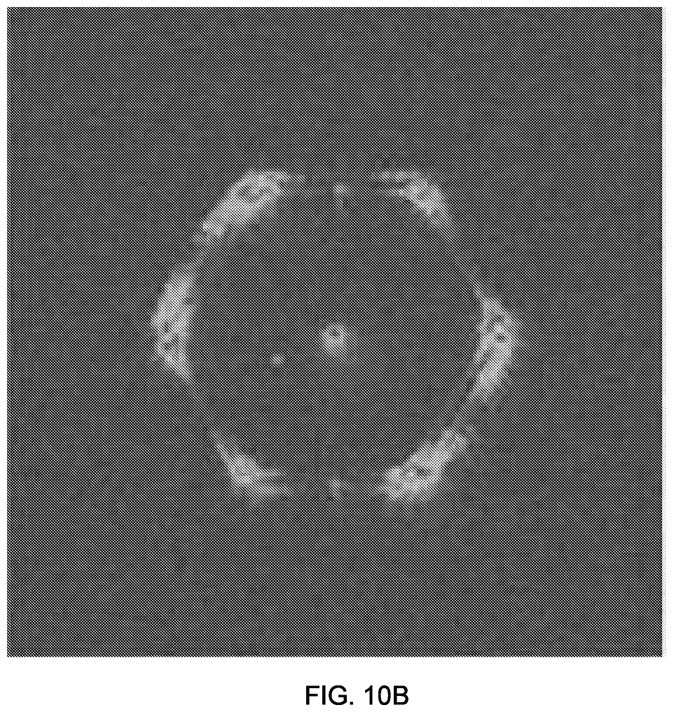

Some embodiments of the present technology are directed to systems and methods for the creation of Neel type skyrmion in uniaxial centrosymmetric ferromagnetic thin-film materials at room temperature. Some embodiments include a CDIMOM 10 tested on an optically transparent YIG thin film sample 22 in transmission scattering geometry. As shown in FIG. 3A, the YIG sample 22 is placed in the sample environment block 12 of CDIMOM 10 for exposure to magnetic fields generated by the surrounding plurality of programmable magnets 23. In some embodiments, the sample 22 is placed on a substrate 31, as shown in FIG. 3B. FIGS. 4A-9B show in-plane magnetic fields generated by various positioning of the programmable magnets 23, and the corresponding polarized coherent diffraction patterns for the respective magnet positions. FIGS. 10A and 10B show simulated and measured polarized coherent diffraction patterns for a rotated magnetic field. In some embodiments, the magnetic field is generated by activating a plurality of stationary electromagnets 23 that surround a sample 22 and varying the voltage and/or current supplied to each of the electromagnets 23. In some embodiments, the rotated magnetic field is generated by activating one or more pairs of electromagnets 23 that are rotated around a sample 22. In some embodiments, the magnetic setup shown is capable of applying 0.5 T magnetic field in a circular and sequential manner at a frequency of up to 60 KHz rate. The six diffraction patterns show the sequential changes in symmetry of the Majorana zero modes under external perturbation. The sample 22 is preferably placed between an analyzer 13 and a polarizer 11 to detect the symmetry and nature of the Majorana bound states.

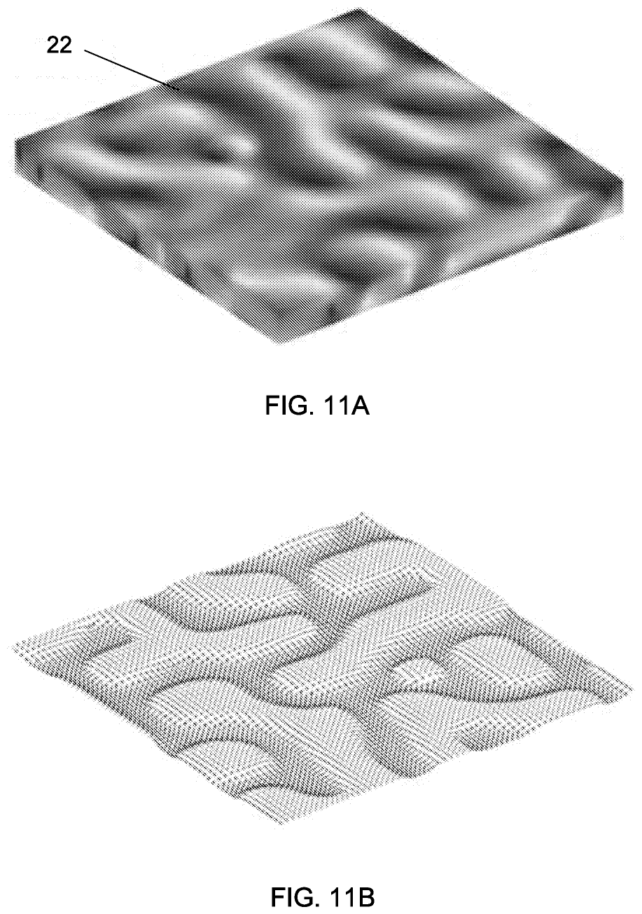

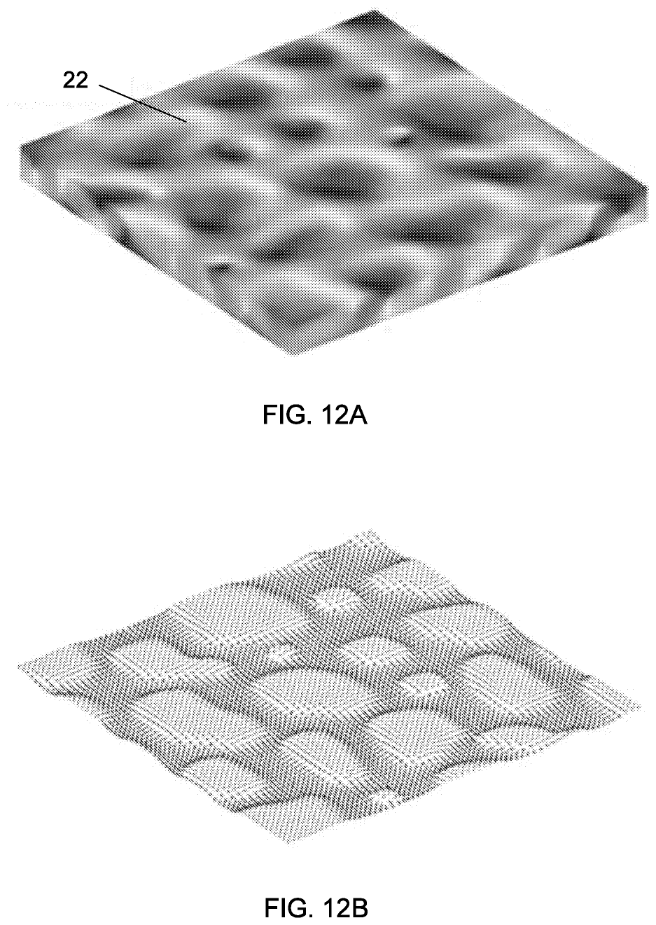

FIG. 11A shows simulation results of stripe domains of the YIG sample 22 without applying the rotated magnetic field, and FIG. 11B shows the magnetic distribution on the top surface of the sample 22. FIG. 12A shows simulation results of skyrmion-like domains of the sample 22 after applying the rotated magnetic field, and FIG. 12B shows the magnetic distribution on the top surface of the sample 22.

In some embodiments, the results are modeled through the following formulas. In the uniaxial ferromagnetic film with perpendicular easy axis, the basic Hamiltonian of the system is:

[symbol]

_{J}=∫[Kᵤ(m₁²+m₂²)+J(∇mᵢ)²]dV, i=1, 2, 3 (3)

where Kᵤ represents the uniaxial energy coefficient, and J is the exchange energy constant. The demagnetic field energy is written as:

[symbol]

_{d}=∫1/2∫H_{d}·mdV (4)

where H_{d} is the stray field that is determined by the long-range interaction among the magnetic moments:

$${H}_{d} = \frac{1}{4 π} \int dV \frac{M ( r ) \cdot M ( {r}^{′} )}{{r}^{3}} - \frac{3 [ M ( r ) \cdot r ] [ M ( {r}^{′} ) \cdot r ]}{{r}^{5}} \qquad ( 5 )$$

where r=|r−r′|. The Zeeman energy from the external applied field is [symbol] ₑₓₜ=−∫Hₑₓₜ·MdV. Thus, the total energy of the system is [symbol] = [symbol] _{J}+ [symbol] _{d}+ [symbol] ₑₓₜ. The temporal evolution of the magnetization configuration is obtained by solving the Landau-Lifshitz-Gilbert (“LLG”) equation:

$$( 1 + {α}^{2} ) \frac{\partial M}{\partial t} = - {γ}_{0} M \times {H}_{eff} - \frac{{γ}_{0} {α}_{0} M}{{M}_{s}} \times M \times ( M \times {H}_{eff} ) \qquad ( 6 )$$

where

$${H}_{eff} = - \frac{1}{{μ}_{0}} \frac{\partial ℋ}{\partial M}$$

is the effective magnetic field, and μ₀ is the permeability of vacuum.

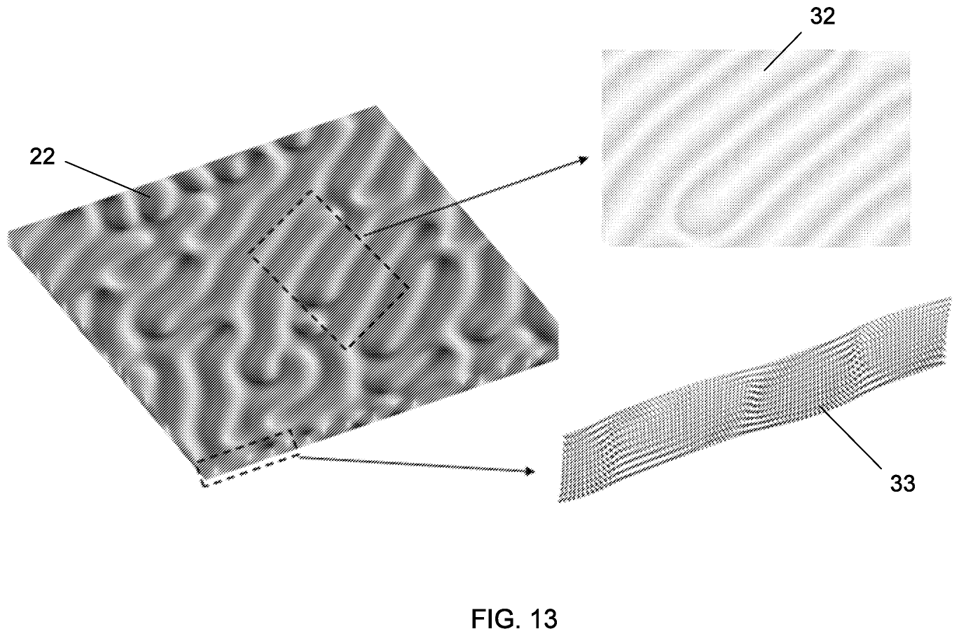

FIG. 13 shows experiment results of the stripe domains of the YIG sample 22 without an external magnetic field, with detail section 32 showing the in-plane magnetization distribution of the sample 22, and detail section 33 showing the vertex domain walls between the stripe domains.

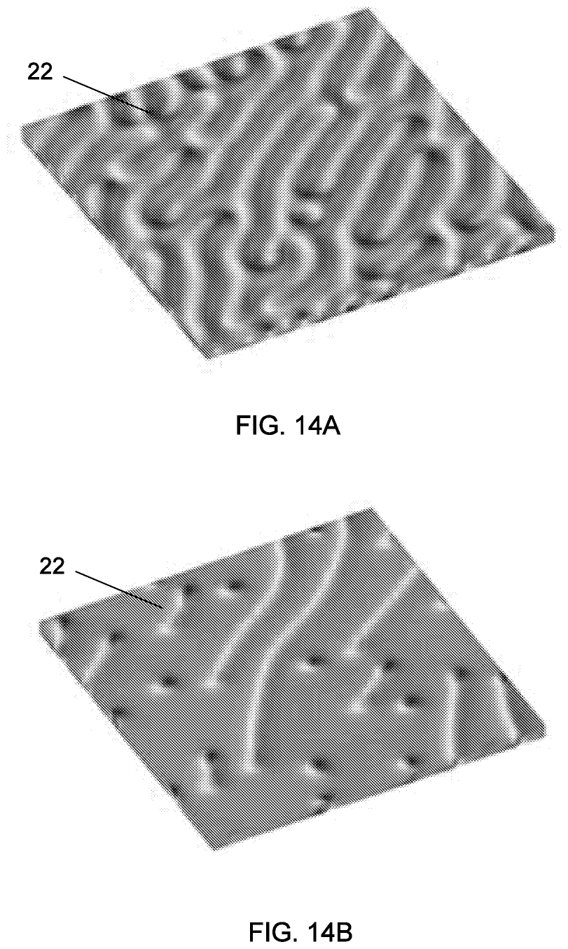

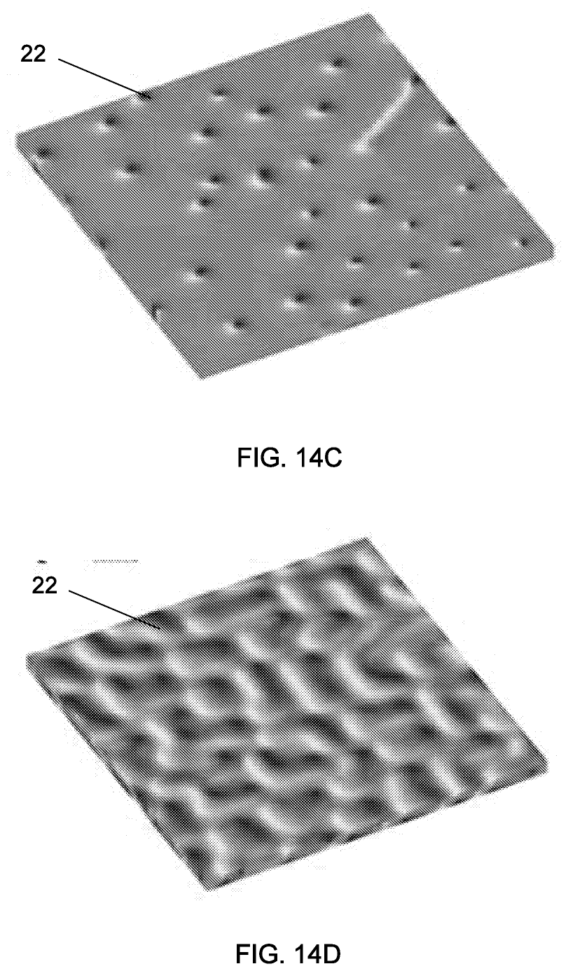

FIGS. 14A-14D show experiment results of the skyrmion domain structure formed in the YIG sample 22 under an external field H_{z} along the z-axis of the sample 22 (as shown in FIG. 3B). FIG. 14A shows the results when H_{z}=0; FIG. 14B shows the results when H_{z}=98 Oe; FIG. 14C shows the results when H_{z}=137 Oe; and FIG. 14D shows the results when H_{z}=0 Oe. As shown, the skyrmion-like bubble domain is not stable when H_{z} is decreased to zero.

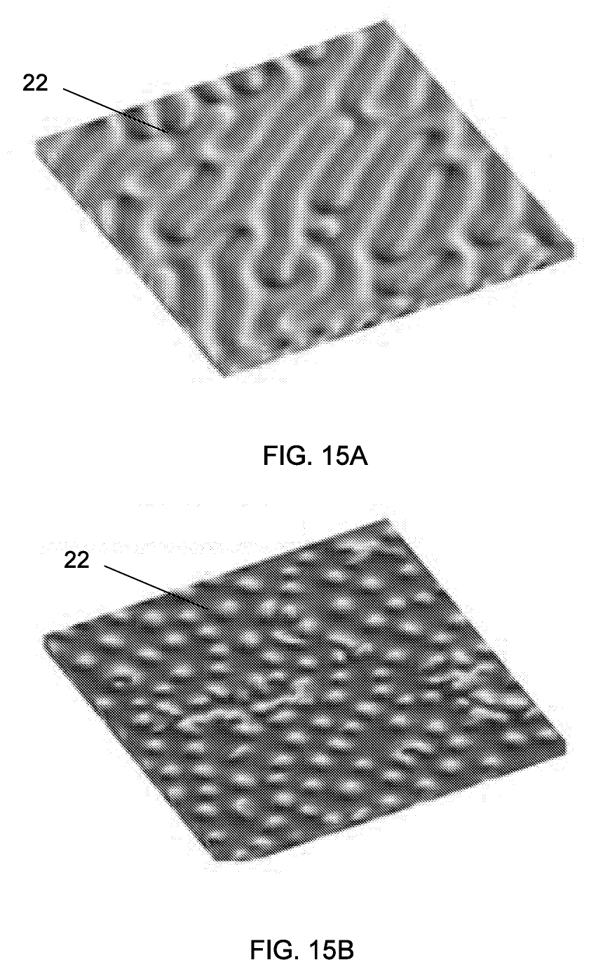

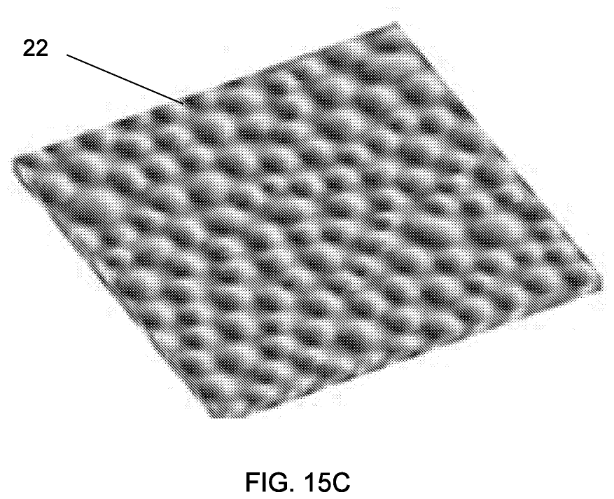

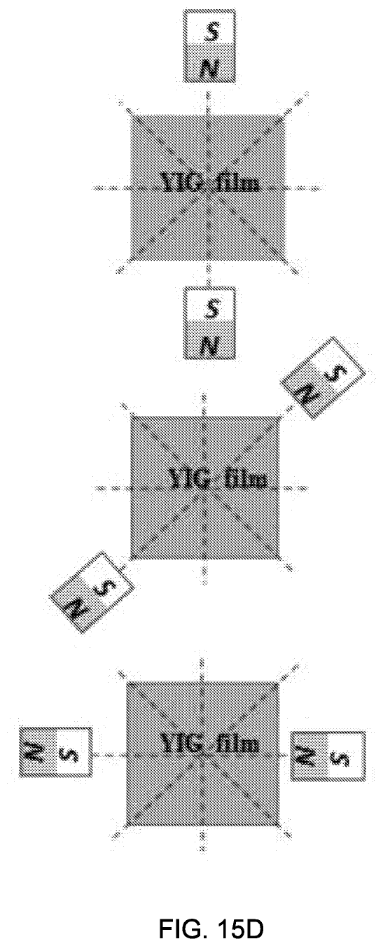

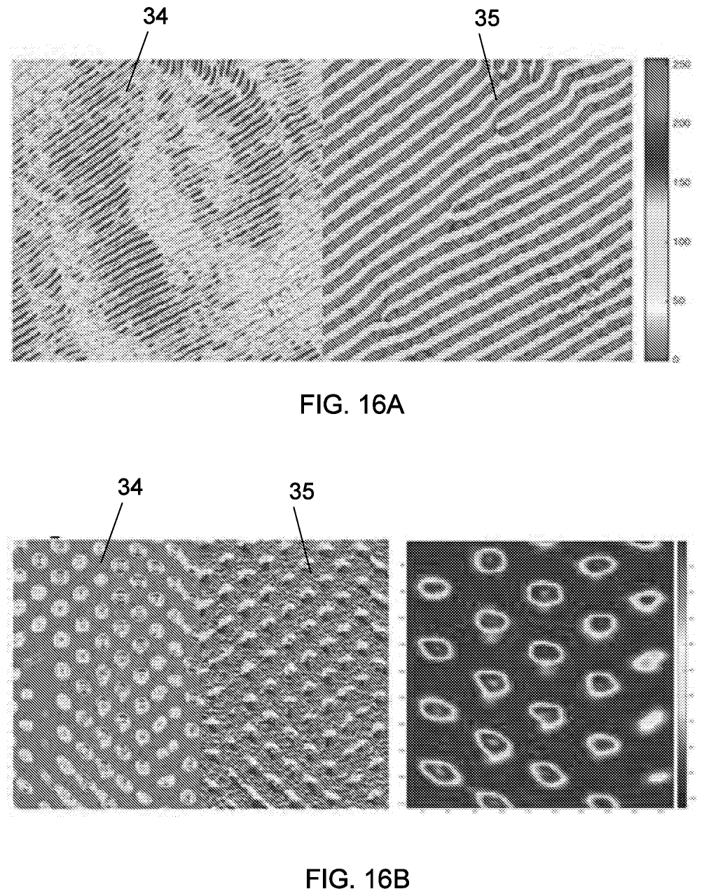

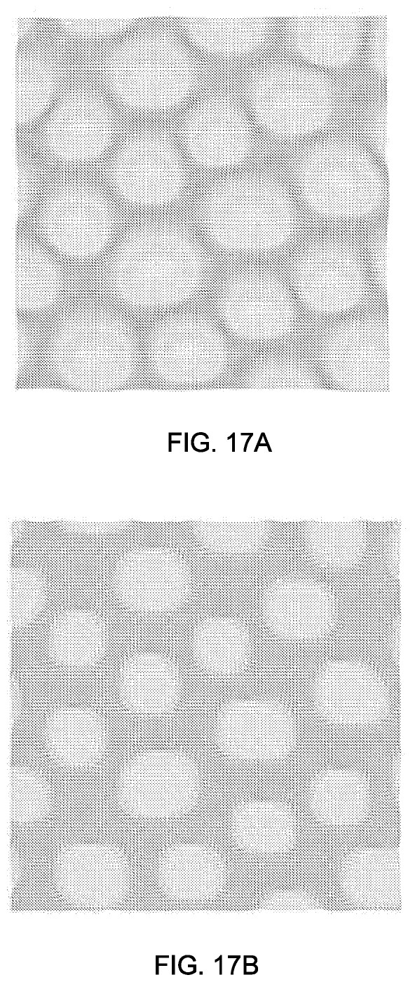

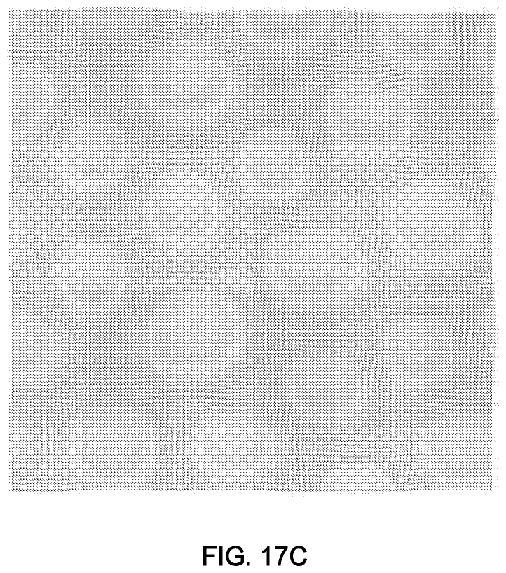

FIGS. 15A-D show experimental results of the skyrmion domain structure formed in the YIG sample 22 under a cycled external field. In some embodiments, the bias field normal to the film is 39 Oe. FIG. 15A shows the stripe domains without the external field. FIG. 15B shows that the stripe domains split into small skyrmion-like bubble domains under the cycled magnetic field after several minutes. FIG. 15C shows that the skyrmion-like bubble domains remain stable even without the external field. FIG. 15D shows an exemplary cycled magnetic field generated by rotating two opposing magnets 23 around the sample 22. FIG. 16A shows gradient magnitude 34 and gradient direction 35 of the stripe domains without applying the rotated magnetic field, and FIG. 16B shows the gradients 34/35 of the skyrmion-like domains after applying the rotated magnetic field. FIGS. 17A-17C show top, central, and bottom slices, respectively, of the YIG sample 22 showing a skyrmion-to-bubble-to-skyrmion transformation.

Although the technology has been described and illustrated with respect to exemplary embodiments thereof, it should be understood by those skilled in the art that the foregoing and various other changes, omissions, and additions may be made there and thereto, without departing from the spirit and scope of the present technology.

1. A system for imaging, comprising:
a source of coherent light;
a polarization state generator for generating polarized optical photons from the light originating in the source of coherent light;
a sample environment, comprising
a plurality of electromagnets, each connected to one or more power supply components via one or more electronic circuits for supplying voltage to the plurality of electromagnets to generate a desired magnetic field; and
a controller, connected to the electromagnets and including software for generating and controlling the desired magnetic field created by each of the plurality of electromagnets in concert with each other;
a polarization state analyzer for permitting photons having a desired polarization to interact with a detector; and
an imaging unit for generating an image based on the interactions of the photons with the detector;
wherein the sample environment creates a multi-pole complex magnetic field having variable shape, variable amplitude, and variable frequency.

2. (canceled)

3. (canceled)

4. (canceled)

5. The system of claim 1, wherein the sample environment creates a rotated magnetic field.

6. The system of claim 5, wherein the rotated magnetic field has a magnetic flux density of 0.5 T and a frequency of up to 60 KHz.

7. The system of claim 1, wherein the sample environment further comprises a sample holder positioned such that the plurality of electromagnets surround the sample holder.

8. The system of claim 1, wherein each of the plurality of electromagnets are held within a magnet holder and located in a magnet housing positioned to surround a sample holder in the sample environment.

9. The system of claim 8, wherein the magnet housing is rotatable around the sample holder.

10. The system of claim 8, wherein the magnet housing has an octagonal shape or an annular shape.

11. (canceled)

12. The system of claim 1, further comprising one or more filtering optics positioned between the polarization state generator and the sample environment.

13. The system of claim 1, further comprising one or more collimating optics positioned between the polarization state generator and the sample environment.

14. The system of claim 1, further comprising one or more alignment mirrors positioned between the polarization state generator and the sample environment.

15. The system of claim 1, wherein the sample environment is a cryo-free environment.

16. The system of claim 1, wherein the polarization state analyzer is reconfigurable between a plurality of modes.

17. The system of claim 16, wherein the plurality of modes of the polarization state analyzer comprises an imaging mode and a diffraction mode.

18. (canceled)

19. A method of creating Neel type skyrmion domains in a sample, comprising:
placing the sample in a sample environment, the sample environment comprising:
a sample holder; and
a plurality of electromagnets arranged to surround the sample holder; and
applying a rotated magnetic field generated by the plurality of electromagnets to the sample to induce bubble skyrmionic polarization dipole textures in the sample.

20. The method of claim 19, wherein the sample environment further comprises:
one or more power supply components connected to each of the plurality of electromagnets;
one or more electronic circuits to bridge the one or more power supply components to the electromagnets; wherein the electronic circuits supply voltage pulses to the electromagnets to generate the rotated magnetic field; and
a controller, connected to the electromagnets and including software for controlling the magnetic field.

21. The method of claim 19, wherein the sample environment is a cryo-free environment.

22. The method of claim 19, wherein the rotated magnetic field has a magnetic flux density of 0.5 T and a frequency of up to 60 KHz.

23. The method of claim 19, wherein the sample comprises a uniaxial centrosymmetric ferromagnetic thin-film material.

24. The method of claim 23, wherein the sample comprises Y₃Fe₅O₁₂.

25. A system for imaging, comprising:
a source of coherent light;
a polarization state generator for generating polarized optical photons from the light originating in the source of coherent light;
a sample environment, comprising
a sample holder;
a plurality of electromagnets, each connected to one or more power supply components, each of the plurality of electromagnets are held within a magnet holder and located in a magnet housing positioned to surround the sample holder, the magnet housing is rotatable around the sample holder; and
a controller, connected to the electromagnets and including software for generating and controlling a desired magnetic field created by each of the electromagnets in concert with each other;
a polarization state analyzer for permitting photons having a desired polarization to interact with a detector; and
an imaging unit for generating an image based on the interactions of the photons with the detector.
